(19) United States
(12) Patent Application Publication
(10) Pub. No.: US 2024/0421139 A1
(43) Pub. Date: Dec. 19, 2024

(54) MODULE ASSEMBLY OF MULTIPLE SEMICONDUCTOR DEVICES WITH INSULATING SUBSTRATES

(71) Applicant: Transphorm Technology, Inc., Goleta, CA (US)

(72) Inventors: Davide Bisi, Goleta, CA (US); Geetak Gupta, Goleta, CA (US); Tsutomu Hosoda, Kawagoe (JP); Umesh Mishra, Montecito, CA (US)

(21) Appl. No.: 18/719,758

(22) PCT Filed: Dec. 21, 2022
(86) PCT No.: PCT/US2022/082182

§ 371 Date: Jun. 13, 2024

Related U.S. Application Data
(60) Provisional application No. 63/292,905, filed on Dec. 22, 2021.

(51) Int. Cl. H01L 25/16; H01L 23/00; H01L 23/04; H01L 23/373; H01L 23/538; H01L 27/12; H01L 29/20; H01L 29/778; H01L 29/78

(52) U.S. Cl. CPC H01L 25/165; H01L 23/04; H01L 23/373; H01L 23/5385; H01L 24/32; H01L 24/48; H01L 24/73; H01L 27/1203; H01L 29/2003; H01L 29/7786; H01L 29/7827; H01L 2224/32221; H01L 2224/48175; H01L 2224/73265

(57) ABSTRACT

An electronic component comprising and electronic component package including a high thermally conductive package base. The component further includes a first lateral III-N device including a first insulating substrate, the first lateral III-N device comprising a first side and a second side, where a first III-N material structure is on the first side of the first lateral III-N device. A second lateral III-N device including a second insulating substrate, the second lateral III-N device comprising a first side and a second side, where a second III-N material structure is on a first side of the second lateral III-N device. The second side of the first lateral III-N device is directly mounted and physically attached to the thermally conductive package base and the second side of the second lateral III-N device is directly mounted and physically attached to the thermally conductive package base.

### CROSS-REFERENCE TO RELATED APPLICATIONS

This application is a National Stage Application under 35 U.S.C. § 371 and claims the benefit of International Application No. PCT/US2022/082182, filed Dec. 21, 2022, which claims the benefit under 35 U.S.C. § 119 (e) of priority to Provisional Application No. 63/292,905, filed on Dec. 22, 2021. The disclosure of each of the foregoing applications is incorporated herein by reference.

### TECHNICAL FIELD

The disclosed technologies relate to semiconductor electronic devices and modules.

### BACKGROUND

Currently, typical power semiconductor devices, including devices such as transistors, diodes, power MOSFETs and insulated gate bipolar transistors (IGBTs), are fabricated with silicon (Si) semiconductor material. More recently, wide-bandgap materials (e.g., III-N) have been considered for power devices due to their superior properties. III-Nitride or III-N semiconductor devices, such as gallium nitride (GaN) devices, are now emerging as attractive candidates to carry large currents, support high voltages, and provide very low on-resistance with fast switching times and low power losses. In order to reduce the cost of GaN power devices and compete with incumbent silicon power devices, GaN power devices are typically fabricated on electrically conductive or semi-conductive silicon substrates (i.e., GaN-on-Silicon), which are easily compatible with existing silicon fabrication facilities.

Electronic modules containing two or more semiconductor devices fabricated on conductive or semi-conductive substrates, such as silicon, are typically assembled on a direct bonded copper board (i.e., a DBC) or a printed circuit board (PCB) with an isolation layer (typically a ceramic layer such as AlN), to ensure electrical isolation between the semiconductor devices. This electrical isolation is required for proper operation of the modules.

A cross sectional view of the prior-art is illustrated in FIG. 1. Module 100 of FIG. 1 includes a module package cover 10 which can be a plastic or metal package cover. Module 100 includes a structural package base 11 formed of a high thermally conductive material (e.g., a metal, such as Copper, Aluminum, Nickel). The package cover 10 and the structural package base 11 form a package assembly to protect the internal electronic components from environmental elements.

The module 100 includes a board 12 which can be, for example, a direct bonded copper (DBC) substrate or a printed circuit board (PCB), which can be a base substrate for the module. In general, the package base 11 can be considered to include the layer to which to the package cover 10 is attached, and any layers further from the board 12 (but not the board 12 itself or layers closer to the board 12).

For the purpose of simplicity, board 12 of module 100 is a DBC substrate. A DBC substrate is formed by direct bonding of pure copper in a high temperature melting and diffusion process to a ceramic insulator such as AlN or Al₂O₃. The DBC substrate 12 includes an insulating layer 14 (e.g., ceramic, AlN, or Al₂O₃), between a bottom metal layer 13 (e.g., copper or nickel) and a top metal layer (e.g., copper or nickel). The top metal layer is patterned into at least a first portion 15, a second portion 16, a third portion 17, a fourth portion 18, and a fifth portion 19. Portions 15-19 are each electrically isolated from one another by a trench 25 formed through the top metal layer of DBC 12.

Module 100 further includes a first semiconductor device 20 and a second semiconductor device 30, where either device 20 or 30 can be, for example, a vertical or lateral FET, IGBT, MOSFET, JFET, HEMT or other appropriate device. In this embodiment, the first and second semiconductor devices 20 and 30 shown in FIG. 1 are lateral devices. The first device 20 is formed on a conductive or semiconductive substrate 21 (e.g., Si, SiC or GaN). The first device 20 includes a first source electrode 22 and a first drain electrode 23 and is attached to the second portion of the top metal layer 16 with an adhesion layer 24 (e.g., solder, epoxy, or solder paste).

Module 100 further includes a second semiconductor device 30, which can be, for example, a lateral or vertical FET, IGBT, MOSFET, JFET, HEMT or other appropriate device. The second device 30 is formed on a conductive or semiconductive substrate 31 (e.g., Si, SiC or GaN). The second device 30 includes a second source electrode 32 and a second drain electrode 33 and is attached to the fourth portion of the top metal layer 18 with an adhesion layer 34 (e.g., solder, epoxy, or solder paste).

Connector 41 electrically connects the first drain electrode 22 to the first portion of the top metal layer 15. Connector 42 electrically connects the first source electrode 23 to the third portion of the top metal layer 17. Connector 43 electrically connects the second drain electrode 32 to the third portion of the top metal layer 17. Connector 44 electrically connects the second source electrode 33 to the fifth portion of the top metal layer 19. Connectors 41-44 can be formed of wire-bonds, copper clips, wire ribbons, etc. To insure electrical isolation of the first semiconductor device 20 and the second semiconductor device 30, the insulating layer 14 is used to isolate and separate the devices from the thermally conductive structural package base 11 within module 100. The thickness of insulator layer 14 can commonly be greater than 200 μm thick.

### SUMMARY

Described herein are integrated designs for lateral devices (e.g., GaN HEMT power transistors), for which an insulating substrate is used to integrate the device into the component packaging, or electronic module, to improve the thermal performance of the module. The term “device” will be used in general for any transistor, or switch, or diode when there is no need to distinguish between them.

In a first aspect, an electronic component is described. The electronic component includes and electronic component package including a high thermally conductive package base. The component further includes a first lateral III-N device including a first insulating substrate, the first lateral III-N device comprising a first side and a second side, where a first III-N material structure is on the first side of the first lateral III-N device. A second lateral III-N device including a second insulating substrate, the second lateral III-N device comprising a first side and a second side, where a second III-N material structure is on a first side of the second lateral III-N device. The second side of the first lateral III-N device is directly mounted and physically attached to the thermally conductive package base and the second side of the second lateral III-N device is directly mounted and physically attached to the thermally conductive package base.

In a second aspect, an electronic module is described. The module including a package, a high thermally conductive package base, and a substrate mounted to the package base. The substrate comprising a first metal layer on an insulating layer, the first metal layer including a first portion, a second portion, and a third portion. The substrate further including a first opening and a second opening, where the first metal layer and the insulating layer are removed in the first opening and the second opening to expose a top surface of the package base, and a first semiconductor device is mounted to the package base in the first opening, and second semiconductor device is mounted to the package base in the second opening.

In a third aspect, an electronic module is described. The electronic module includes a package, a thermally conductive package base, a high-side switch, a low-side switch, a high-voltage terminal, an output terminal, and a ground terminal. The high-side switch comprising a first III-N depletion-mode transistor and a first enhancement-mode transistor, and the low-side switch comprising a second III-N depletion-mode transistor and a second enhancement-mode transistor. A drain electrode of the first III-N depletion-mode transistor is electrically connected to the high-voltage terminal, a source electrode of the first enhancement-mode transistor is electrically connected to the output terminal, a drain electrode of the second III-N depletion-mode transistor is electrically connected to the output terminal, and a source electrode of the second enhancement-mode transistor is electrically connected to the ground terminal, where a substrate of the first and second III-N depletion-mode transistors is directly physically attached to the high thermally conductive package base.

Each of the devices, transistor, and modules described herein can include one or more of the following features. The insulating substrates can be a sapphire substrates. The first and second insulating substrates includes a backmetal layer, and the backmetal layer is attached to the package base using a thermally conductive solder, a thermally conductive epoxy, or a thermally conductive solder paste. A printed circuit board (PCB) can be within the component package, the PCB including an insulating layer, a first side, and a second side opposite the first side, where the first side of the PCB includes a first metal layer physically attached to the package base. The second side of the PCB can include a second metal layer, and the second metal layer includes at least a first portion, a second potion, and a third portion, where the first portion, the second portion, and the third portion are each electrically isolated from the other portions. The drain electrode of the first lateral III-N device is electrically connected to the first portion, the drain electrode of the second lateral III-N device is electrically connected to the second portion, the source electrode of the first lateral III-N device is electrically connected to the second portion, and the source electrode of the second lateral III-N device is electrically connected to the third portion. A first vertical MOSFET device, where the drain electrode of the MOSFET device is electrically connected and physically attached to the source electrode of the first lateral III-N device. A second vertical MOSFET device where the drain of the second MOSFET is electrically connected and physically attached to the source of the second III-N device. A resistor, capacitor, or IC is mounted to the second side of the PCB. The PCB is physically isolated from the package base. The device can be a high-voltage device with a breakdown voltage greater than 600V and an on-resistance of less than 15 mohm. The first portion of the first metal layer is connected to a high-voltage terminal, the second portion of the first metal layer is connected to an output terminal, and the third portion of the first metal layer is connected to a ground terminal. The high-side (first semiconductor device) and low-side (second semiconductor device) switches of the electronic module can form a half-bridge circuit. The high-side switch and the low-side switch can be encased in a single electronic package. The first and second III-N depletion-mode transistors are lateral GaN HEMT transistors. The first and second enhancement-mode transistors are vertical silicon MOSFET transistors.

As used herein, a “hybrid enhancement-mode electronic device or component”, or simply a “hybrid device or component”, is an electronic device or component formed of a depletion-mode transistor and an enhancement-mode transistor, where the depletion-mode transistor is capable of a higher operating and/or breakdown voltage as compared to the enhancement-mode transistor, and the hybrid device or component is configured to operate similarly to a single enhancement-mode transistor with a breakdown and/or operating voltage about as high as that of the depletion-mode transistor. That is, a hybrid enhancement-mode device or component includes at least 3 nodes having the following properties. When the first node (source node) and second node (gate node) are held at the same voltage, the hybrid enhancement-mode device or component can block a positive high voltage (i.e., a voltage larger than the maximum voltage that the enhancement-mode transistor is capable of blocking) applied to the third node (drain node) relative to the source node. When the gate node is held at a sufficiently positive voltage (i.e., greater than the threshold voltage of the enhancement-mode transistor) relative to the source node, current passes from the source node to the drain node or from the drain node to the source node when a sufficiently positive voltage is applied to the drain node relative to the source node. When the enhancement-mode transistor is a low-voltage device and the depletion-mode transistor is a high-voltage device, the hybrid component can operate similarly to a single high-voltage enhancement-mode transistor. The depletion-mode transistor can have a breakdown and/or maximum operating voltage that is at least two times, at least three times, at least five times, at least ten times, or at least twenty times that of the enhancement-mode transistor.

As used herein, the terms III-Nitride or III-N materials, layers, devices, etc., refer to a material or device comprised of a compound semiconductor material according to the stoichiometric formula B_{w}AlₓIn_{y}Ga_{z}N, where w+x+y+z is about 1 with 0≤w≤1, 0≤x≤1, 0≤y≤1, and 0≤z≤1. III-N materials, layers, or devices, can be formed or prepared by either directly growing on a suitable substrate (e.g., by metal organic chemical vapor deposition), or growing on a suitable substrate, detaching from the original substrate, and bonding to other substrates.

As used herein, two or more contacts or other items such as conductive channels or components are said to be “electrically connected” if they are connected by a material which is sufficiently conducting to ensure that the electric potential at each of the contacts or other items is intended to be the same, e.g., is about the same, at all times under any bias conditions.

As used herein, “blocking a voltage” refers to the ability of a transistor, device, or component to prevent significant current, such as current that is greater than 0.001 times the operating current during regular conduction, from flowing through the transistor, device, or component when a voltage is applied across the transistor, device, or component. In other words, while a transistor, device, or component is blocking a voltage that is applied across it, the total current passing through the transistor, device, or component will not be greater than 0.001 times the operating current during regular conduction. Devices with off-state currents which are larger than this value exhibit high loss and low efficiency, and are typically not suitable for many applications, especially power switching applications.

As used herein, a “high-voltage device”, e.g., a high-voltage switching transistor, HEMT, bidirectional switch, or four-quadrant switch (FQS), is an electronic device which is optimized for high-voltage applications. That is, when the device is off, it is capable of blocking high voltages, such as about 300V or higher, about 600V or higher, or about 1200V or higher, and when the device is on, it has a sufficiently low on-resistance (R_{ON}) for the application in which it is used, e.g., it experiences sufficiently low conduction loss when a substantial current passes through the device. A high-voltage device can at least be capable of blocking a voltage equal to the high-voltage supply or the maximum voltage in the circuit for which it is used. A high-voltage device may be capable of blocking 300V, 600V, 1200V, 1700V, 2500V, or other suitable blocking voltage required by the application. In other words, a high-voltage device can block all voltages between 0V and at least Vₘₐₓ, where Vₘₐₓ is the maximum voltage that can be supplied by the circuit or power supply, and Vₘₐₓ can for example be 300V, 600V, 1200V, 1700V, 2500V, or other suitable blocking voltage required by the application. For a bidirectional or four quadrant switch, the blocked voltage could be of any polarity less a certain maximum when the switch is OFF (±Vₘₐₓ such as ±300V or ±600V, ±1200V and so on), and the current can be in either direction when the switch is ON.

As used herein, the terms “over,” “under,” “between,” and “on” refer to a relative position of one layer with respect to other layers. As such, for example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in contact with that second layer. Additionally, the relative position of one layer with respect to other layers is provided assuming operations are performed relative to a substrate without consideration of the absolute orientation of the substrate.

As used herein, an electrode refers to the metal layers within a device or transistor which are connected to either the source, gate or drain of the device. A “pad” such as a “source pad, drain pad, or gate pad” refer to the uppermost un-passivated portion of the electrode from the semiconductor material which is used to electrically connect the device or transistor to the package e.g., with solder, epoxy, wire-bonds and/or metal clips.

As used herein, a material with a high thermal conductivity is defined as a material with a thermal conductivity greater than 1 (one) as measured in watts per meter-kelvin.

The details of one or more disclosed implementations of the subject matter described in this specification are set forth in the accompanying drawings and the description below. Additional features and variations may be included in the implementations as well. Other features, aspects, and advantages will become apparent from the description, the drawings and the claims.

### DESCRIPTION OF DRAWINGS

FIG. 1 is a cross-sectional view of an electronic module of the prior art.

FIG. 2A and FIG. 2B are a cross-sectional and a plan view, respectively, of an electronic module including semiconductor devices formed on insulating substrates.

FIG. 3 is a cross-sectional view of an electronic module including a hybrid III-N device.

FIG. 4A is a plan view of an electronic module including semiconductor devices formed on insulating substrates.

FIGS. 4B-4D are illustrative cross-sectional side views of electronic modules including insulating substrates.

FIG. 5A and FIG. 5B are illustrative cross-sectional side views of electronic modules including insulating substrates.

FIG. 5C is a plan view of the electronic module shown in FIG. 5B.

FIG. 5D and FIG. 5E are illustrative cross-sectional side views of electronic modules including insulating substrates.

FIG. 6A and FIG. 6B are an illustrative cross-sectional side view and a plan view, respectively, of an electronic module including a monolithically integrated semiconductor device.

FIG. 7 is an illustrative cross-sectional side view of an electronic module including a monolithically integrated semiconductor device.

FIGS. 8A-8D are cross-sectional side views of electronic modules using flip-chip technology.

FIG. 9 is a plan view of a 3-phase electronic module.

### DETAILED DESCRIPTION

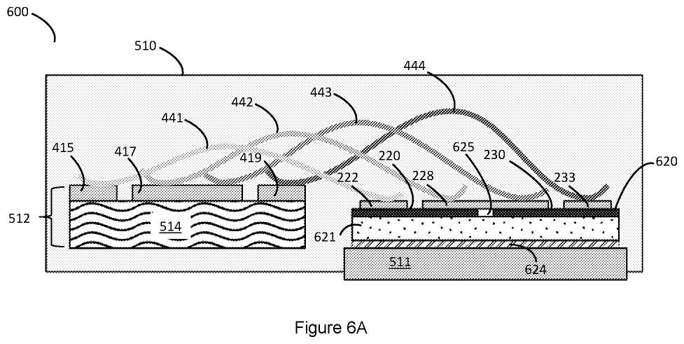

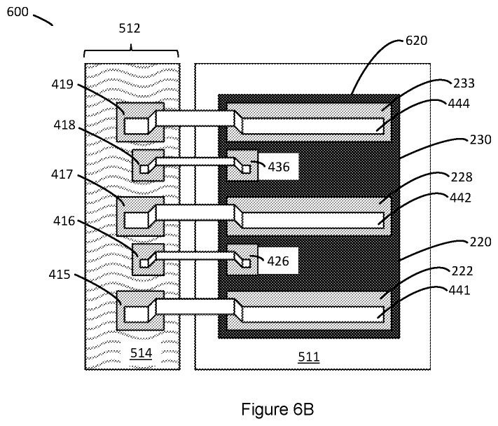

Due to the low cost of silicon substrates and the widely available processing equipment which is compatible with silicon, current industry commercialization efforts are largely focused on forming lateral III-N semiconductor devices (e.g., GaN/AlGaN HEMT devices) on semi-conducting or conducting silicon substrates. However, integration of multiple semiconductor devices formed on silicon substrates into a single electronic module needs electrical isolation between the devices, and therefore can suffer from poor thermal performance due to the required addition of electrical insulation boards between the power devices and the module package base. To insure electrical isolation of the multiple semiconductor devices, an insulating shim is used to isolate and separate the devices from the thermally conductive structural package base within the module. The thickness of insulating shim can commonly be greater than 200 μm thick. However, this introduces a significant thermal resistance between the semiconductor devices and the module package thermal pad and/or heatsink and leads to a degradation in module performance. Hypothetically the insulating shim could be instead replaced with a thin dielectric layer (e.g., SiN), but in this case high breakdown voltages (e.g., upwards of 1200V) would be difficult to achieve, and switching performance would be reduced due to multiple devices becoming capacitively coupled to the same thermally conductive package base. Also, back-gating cross-talk between devices will reduce performance, particularly for monolithically integrated devices such as those described in FIGS. 6A, 7, and 8C. As a result, alternative device designs and module designs are needed to reduce the thermal resistance for applications and modules which have high thermal requirements.

Due to the recent success of the LED lighting market, the price of insulating substrates, such as sapphire substrates, has recently reduced. Furthermore, technologies to fabricate thin insulating substrates, such as sapphire substrates less than 100 μm thick, are now becoming available. Forming semiconductor devices, such as lateral GaN devices on insulating substrates, allows for novel module designs and layout considerations that are not possible with semiconductor devices formed on conductive or semi-conductive substrates such as silicon, silicon carbide, or gallium nitride substrates, due to the inherent semi-conducting properties. This provides opportunities to further improve module performance while simultaneously reducing packaging complexity of III-Nitride devices and transistors formed on insulating substrates.

Described herein are integrated designs for lateral devices (e.g., III-N HEMT devices), for which insulating substrates are used to integrate the devices into the electronic component packaging (e.g., electronic module) in order to improve the electrical and thermal performance. This simultaneously reduces packaging complexity and overall cost of module assembly. As used herein, a lateral device is defined as a semiconductor device for which the source electrode and the drain electrode are formed on the same side of the device substrate.

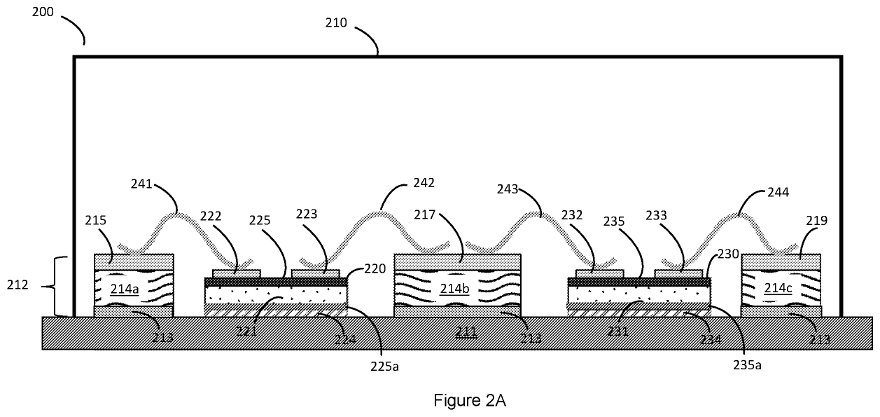

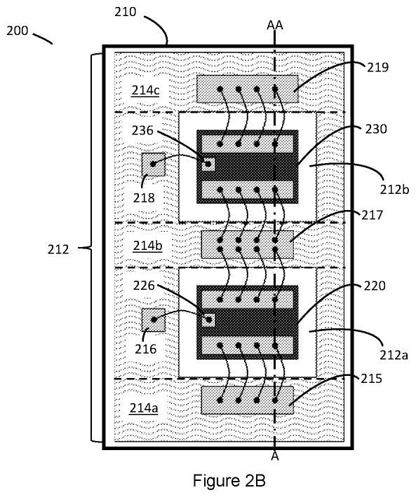

A cross sectional view of electronic module 200, is illustrated in FIG. 2A. Module 200 includes a package cover 210 which can be a plastic, ceramic, or metal package cover and a structural package base 211 formed of a high thermal conductive material (e.g., a metal, such as Copper, Aluminum, or Nickel). The package base 211 can be a single layer of homogenous material. The package cover 210 and the structural package base 211 form a package assembly to protect the internal electronic components from environmental elements. The package base 211 can be considered to be provided by a layer to which to the package cover 210 is attached, and any layers on the side further from the package cover 210 and/or internal electronic components within the module. Although not shown for simplicity, the package base 211 can be configured to be connected to a heat sink. The heat sink can be externally connected. Depending on the heat sink configuration, the module 200 of FIG. 2A can be top-side cooled, or bottom-side cooled.

Module 200 includes a first semiconductor device 220 and a second semiconductor device 230, which either device 220 or 230 can be, for example, a lateral FET, IGBT, MOSFET, JFET, HEMT or other appropriate device. For simplicity, it is assumed that the first and second semiconductor device 220 and 230 are high power III-N HEMT devices capable of blocking voltages greater than 600V. The first device 220 includes a III-N HEMT material structure 225 formed (e.g., grown in a metal organic chemical vapor deposition reactor) on a first side of an insulating device substrate 221 (e.g., a sapphire substrate). The first device 220 further includes a first backside metallization layer 225a formed on, e.g., directly contacting, a second side of the insulating device substrate 221. The first device 220 includes a first source electrode 222 and a first drain electrode 223 formed on a first side of the device 220. A second side of the device 220 (opposite the first side of device 220), e.g., the metallization layer 225a, is directly mounted and physically attached to the thermally conductive structural package base 211 (i.e., without the use of an isolation and/or insulating shim between the first device and the package base) using an adhesion layer 224 (e.g., solder, epoxy, or solder paste which is thermally reflowed with the first backside metallization layer). The thermal reflow may result in the metallization layer 225a and the adhesion layer 224 to form an alloyed portion. Although a metal layer 213 can be used for other devices on the base 211, the first and second devices 220, 230 can be attached to the base 211 without such an intervening layer. In addition, there is no intervening insulating layer (e.g., ceramic, AlN, or Al₂O₃ shim) to electrically isolate the first device 220 from the package base 211.

Module 200 further includes a second semiconductor device 230, which can be, for example, a lateral FET, IGBT, MOSFET, JFET, HEMT or other appropriate device. For simplicity, we can assume the second semiconductor device 230 is a high power III-N HEMT devices capable of blocking voltages greater than 600V. The second device 230 includes a III-N HEMT material structure 235 formed on a first side of an insulating device substrate 231 (e.g., sapphire). The second device 230 further includes a second backside metallization layer 235a formed on, e.g., directly contacting, a second side of the insulating device substrate 231. The second device 230 further includes a second source electrode 232 and a second drain electrode 233 formed on a first side of the device 230. A second side of device 230 (opposite the first side of device 230), e.g., the metallization layer 235a, is directly mounted and physically attached to the thermally conductive structural package base 211 (i.e., without the use of an isolation and/or insulating shim between the first device and the package base) using an adhesion layer 234 (e.g., solder, epoxy, or solder paste which is thermally reflowed with the second backside metallization layer). There is no intervening insulating layer (e.g., ceramic, AlN, or Al₂O₃ shim) or bottom metal layer to electrically isolate the second device 230 from the package base 211.

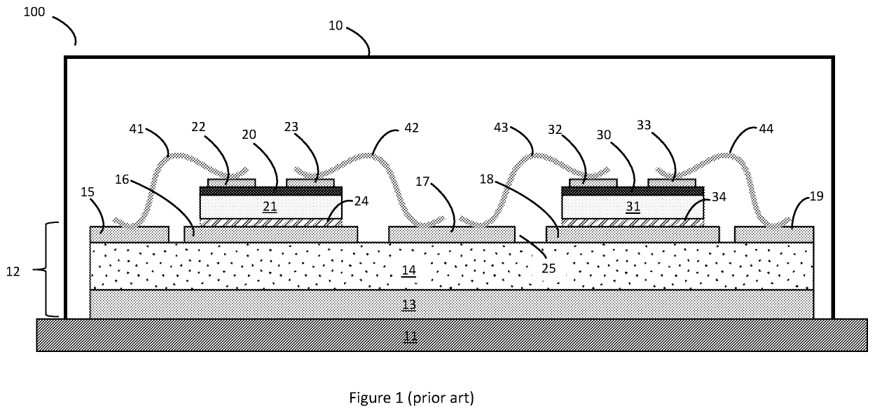

Referring back to FIG. 1, an insulating layer 14 (e.g. ceramic, AlN, or Al₂O₃ shim) is needed to electrically isolate device 20 from device 30 when device 20 and device 30 are formed with, for example, a semiconductive silicon device substrate. However, as shown in FIG. 2A, when device 220 and device 230 are formed with, for example, an insulating sapphire device substrate, the insulating layer 14 can be omitted below both the first device 220 and the second device 230, such that both the first device 220 and the second device 230 are directly physically attached to the high thermally conductive package base 211.

The first and second device 220 and 230, respectively, can be high power semiconductor devices with a high breakdown voltage, for example, greater than 600V or even greater than 1200V. They can be configured into several different common circuitry topologies. For example, the first device 220 can be a low-side transistor, and the second device 230 can be a high-side transistor, and the first and second devices can be configured into a half-bridge circuit. Alternatively, the first and second devices 220 and 230 can be configured to operate as a bi-directional switch (commonly referred to as a Four-Quadrant Switch or FQS). In addition, the module 200 and all subsequently described modules withing this specification may not be limited to only two devices, such that the configurations of the modules described herein can serve as a basic building block which can be expanded or multiplied as need to fit the designers requirements. For example, any module described herein may include two or more low-side transistors connected in parallel or two or more high-side transistors connected in parallel. Furthermore, the devices described herein may be configured to form a three-phase inverter. The circuits and modules described herein may include additional electronic components such as capacitors, resistors, inductors, driving transistors, and diodes as needed to safely and effectively operate the circuit.

Devices fabricated on insulating device substrates (e.g., sapphire substrates) can include a backside metallization layer (such as layer 225a and 235a), for example, a Ti/Ni/Ag layer under the insulating device substrate. This backside metallization layer is used to physically attach (e.g., with solder or epoxy) the device to the component packaging or the thermally conductive structural package base. The backside metallization layer reacts with the solder or epoxy during a thermal reflow process to create the adhesion layers 224 and 234.

The module 200 further includes a substrate board 212 which can be, for example, a direct bonded copper (DBC) substrate formed by direct bonding of pure copper in a high temperature melting and diffusion process to a ceramic insulator such as AlN or Al₂O₃ or a printed circuit board (PCB), although PCBs have the advantage of lower manufacturing costs. For the purpose of simplicity, board 212 of module 200 is a PCB. The PCB 212 includes a backmetal layer 213 which is physically attached to the thermal conductive package base 211 with solder or epoxy.

The PCB 212 can have at least 3 portions. In some implementations, the portions are formed by patterning the PCB to remove one or more regions of the PCB where the first and second devices 220 and 230 are located. For example, one or more apertures, e.g., two apertures 212a, 212b (one aperture for each of the devices 220 and 230), can be formed through the PCB 212. Removing these regions below the first semiconductor device 220 and the second semiconductor device 230 exposes a top surface of the thermally conductive package base 211 in the regions where the substrate 212 is removed.

The first portion of the PCB 212 includes an insulating layer 214a (e.g., ceramic, AlN, or Al₂O₃), between a bottom metal layer 213 (e.g., copper or nickel) and a top metal layer 215 (e.g., copper or nickel). The top metal layer 215 of the first portion of PCB 212 can be configured to be connected to a ground node of module 200. The second portion of the PCB 212 includes an insulating layer 214b between a bottom metal layer 213 and a top metal layer 217. The top metal layer 217 of the second portion of PCB 212 can be configured to be connected to an output node of module 200. The top metal layer 217 of the second portion of PCB 12 can be formed between the first device 220 and the second device 230. The third portion of the PCB 212 includes an insulating layer 214c, between a bottom metal layer 213 and a top metal layer 219. The top metal layer 219 of the third portion of PCB 212 can be configured to be connected to a high-voltage node of module 200. Top metal portions 215, 217, and 219 are each electrically isolated from one another. For example, PCB 212 can be a single continuous substrate (such as the substrate 12 in FIG. 1) and then patterned and etched to remove at least the top metal layer. In this case, the bottom metal layer and insulating layer of the regions 214a, 214b, 214c would remain physically interconnected. An example of this is shown in FIG. 2B, where cross-section A-AA is depicted in FIG. 2A.

Alternatively, portions of the insulating layer 14 (and optionally, the backmetal layer 13) that extend laterally beyond the top metal portions 215, 217, and 219 can also be removed. Removal of portions of the PCB 212 to electrically isolate the top metal portions 215, 217, and 219 can be performed as part of the same etching operation that forms the openings in the PCB where the first and second devices 220 and 230 are located. Alternatively, PCB 212 can be made up of at least 3 discrete portions and assembled into module 200 around the first and second semiconductor devices 220 and 230, respectively. In this case the bottom metal layer and insulating layer of the regions 214a, 214b, 214c would be separated by gaps.

Referring back to FIG. 2A, a conductive connector 241 electrically connects the first source electrode 222 to the top metal layer 215. The connector 242 electrically connects the first drain electrode 223 to the top metal layer 217. Another conductive connector 243 electrically connects the second source electrode 232 to the top metal layer 217. A third conductive connector 244 electrically connects the second drain electrode 233 to the top metal layer 219. The connectors 241-244 can be formed of wire-bonds, copper clips, wire ribbons, etc. As shown in FIG. 2B, a fourth top metal layer 216 is electrically connected to a first gate electrode 226 of the first device 220 with a wire-bond, and a fifth top metal layer 218 is electrically connected to a second gate electrode 236 of the second device 230 with a wire-bond.

To insure electrical isolation between the first semiconductor device 220 and the second semiconductor device 230, the insulating substrates 221 and 231 of the first and second semiconductor devices are used to electrically isolate and separate the active regions of the devices (i.e., the III-N HEMT structures 225 and 235) from the conductive structural package base 211 within the module 200. The insulating substrates 221 and 231, for example, can be thinned down, e.g., by polishing or etching, to a thickness less than 200 μm, or less than 100 μm. Such small thickness leads to lower thermal resistance between the device active region and the module package base, thus reducing the overall junction-to-case thermal resistance of the module. This improves thermal dissipation, reduces the power losses, and expands the maximum rating of the module (such as max rated DC current). However, if the insulating substrates 221 and 231 are excessively thinned, the breakdown voltage is reduced, negative back-gating effects are increased, and switching interference (i.e. cross-talk) between the multiple devices is increased. As such, the minimum insulating substrate thickness should be greater than 50 μm. Layers 224/234 can be engineered to match the thermal expansion coefficient between the module package base 211 and the substrate to improve robustness and reliability during thermal cycling.

The first device 220 can be a low-side transistor, and the second device 230 can be a high-side transistor, and the first and second devices can be configured into a half-bridge circuit. In a half-bridge circuit, the top metal layer 219 is connected to a high-voltage terminal. The high-voltage terminal is configured to be connected to a high-voltage power supply. The top metal layer 217 is connected to an output terminal. The top metal layer 215 is connected to a ground terminal. The ground terminal is configured to be connected to a circuit ground.

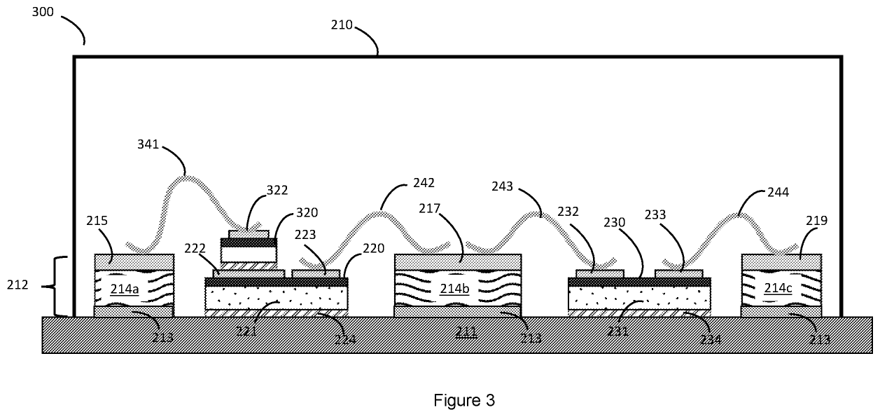

FIG. 3 is a cross-sectional view of another module 300. This module 300 is similar to the module 200 of FIG. 2A, except that module 300 includes stacked semiconductor devices. As seen in FIG. 3, module 300 includes a semiconductor device 320, which can be a vertical enhancement mode (normally-off) device such as a Silicon FET. Device 220 can be a lateral depletion mode (normally-on) device, such as a GaN HEMT. In this case, the enhancement mode device 320 and the depletion mode device 220 can be arranged into a cascode configuration and operate as a single hybrid normally-off device. Here the drain electrode of device 320 can be directly mounted and electrically connected to the source electrode 222 of device 220. Connector 341 is connected to the source electrode 322 of device 320. Although not shown in FIG. 3, an enhancement mode device similar to device 320 can also be directly mounted and electrically connected to the source electrode 232 of device 230 in a similar manner.

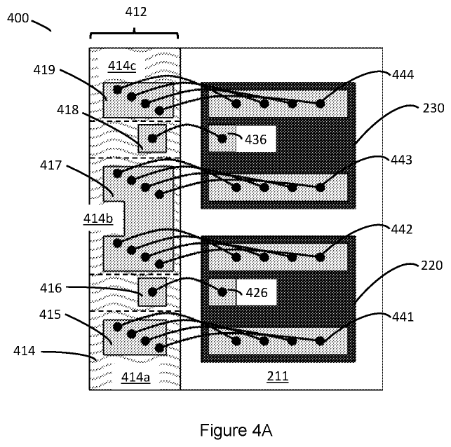

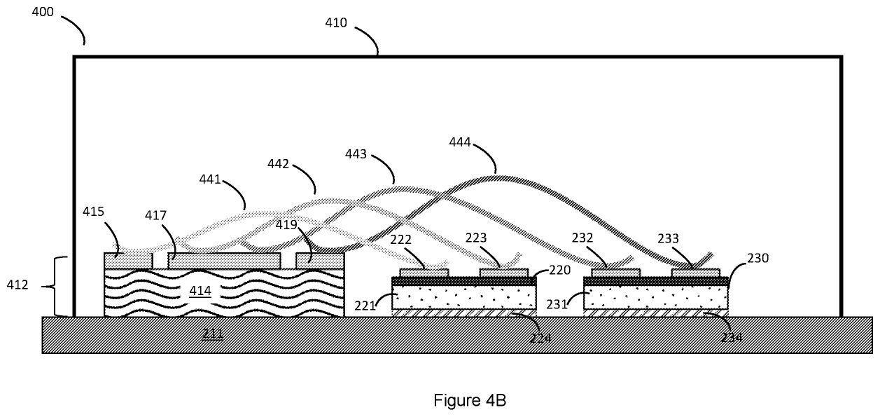

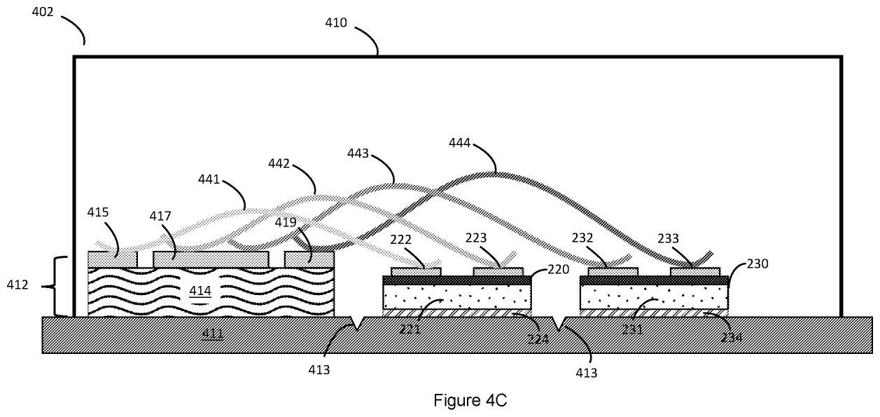

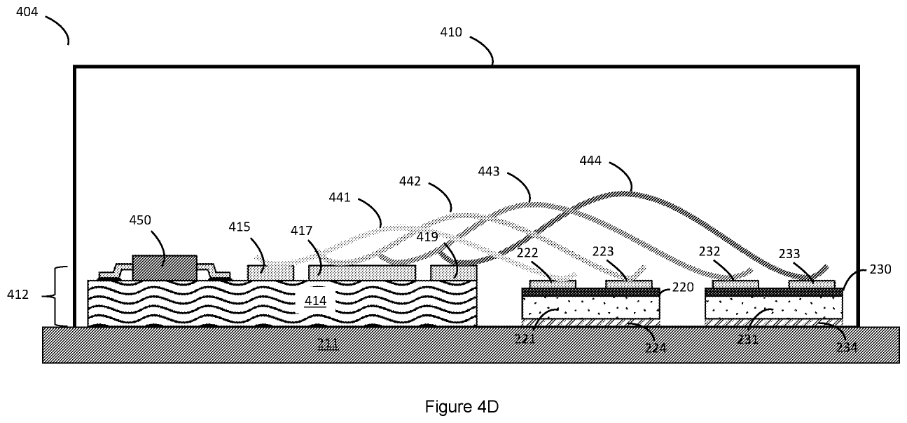

FIG. 4A is a plan view of module 400, and FIG. 4B is a modified illustrative cross-sectional side view of module 400. In FIG. 4B, the features of module 400 are illustrated out of alignment for the sake of viewing simplicity, e.g., so that both devices can be shown in a single side view. However, an intended layout of the features should be construed from the plan view shown in FIG. 4A. Furthermore, these illustrative features are also shown out of alignment in the cross-sectional side views of FIGS. 4C, 4D, 5A, 5B, 5D, 5E, 6A, 7, 8A-8D.

Module 400 is similar to module 200 of FIG. 2A, except that module 400 is arranged with an alternative layout of the PCB 412 compared to module 200. Here, the module 400 includes a single printed circuit board 412 within package 410 where all the top metal layers (415, 416, 417, 418, and 419) are located on the same side of the first device 220 and the second device 230, which is used to make the module wire connections to device 220 and 230 (e.g., the left side of device 220 and 230), compared to using portions of board segments (214b) located between the first device 220 and second device 230, as shown in FIG. 2A. A first portion of PCB 412 includes an insulating layer 414a (e.g., ceramic, AlN, or Al₂O₃) and a top metal layer 415 (e.g., copper or nickel) where the top metal layer 415 is configured to be connected to a ground node of module 400. A second portion of the PCB 412 includes an insulating layer 414b and a top metal layer 417 where the top metal layer 417 is configured to be connected to an output node of module 400. A third portion of the PCB 412 includes an insulating layer 414c and a top metal layer 419 where the top metal layer 419 is configured to be connected to a high-voltage node of module 400.

Referring to FIG. 4B, board 412 includes and insulating layer 414 and multiple top metal layers 415/417/419 where each top metal layer 415/417/419 are electrically isolated from each other. The first source electrode 222 of device 220 is connected to top metal layer 415 with wire connector 441. The first drain electrode 223 of device 220 is connected to top metal layer 417 with wire connector 442. The second source electrode 232 of device 230 is connected to top metal layer 417 with wire connector 443. The second drain electrode 233 of device 230 is connected to top metal layer 419 with wire connector 444. Using an alternative design such as PCB 412 can reduce the assembly cost and provide a lower bill of materials compared to module 200 of FIG. 2A. Referring back to FIG. 4A, the first gate electrode 426 of the first device 220 is connected to top metal layer 416 with a wire connector, and the second gate electrode 436 of the second device 230 connected to top metal layer 418 with a wire connector.

Module 402 of FIG. 4C is similar to module 400 of FIG. 4A, however module 402 in FIG. 4C is assembled with a structural package base 411 which includes solder dam 413. Solder dam 413 can be a “V” shaped groove which can be etched into the package base 411 between the first device 220 and second device 230 to prevent the solder used to attach the first and second devices from reflowing into each other and causing poor device adhesion characteristics. Solder dam 413 can also be etched between the board 412 and the first device 220 and the second device 230 for the same reasons.

Module 404 of FIG. 4D is similar to module 400 of FIG. 4A, however module 404 in FIG. 4D depicts electronic component(s) 450 electrically connected and mounted to the board 412. Electronic component(s) 450 can be, for example, resistors, capacitors, transistors, inductors, diodes, integrated-circuits or other relevant electronic components. Electronic component(s) 450 can be single or multiple bare-dies or can be single or multiple packaged components in an additional case (as depicted in FIG. 4D).

Although not shown for simplicity, the modules 200, 300, 400, 402, 404 of FIGS. 2A, 3, 4A-4D, respectively, contain module leads to connect to external circuitry. These module leads can be power terminals, gate drive terminals, ground terminals, or any other package lead required for proper operation.

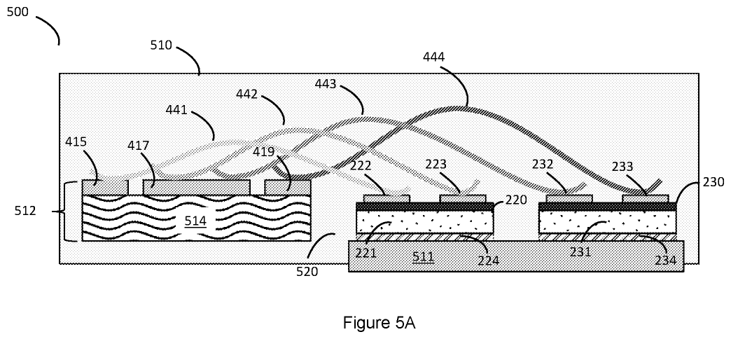

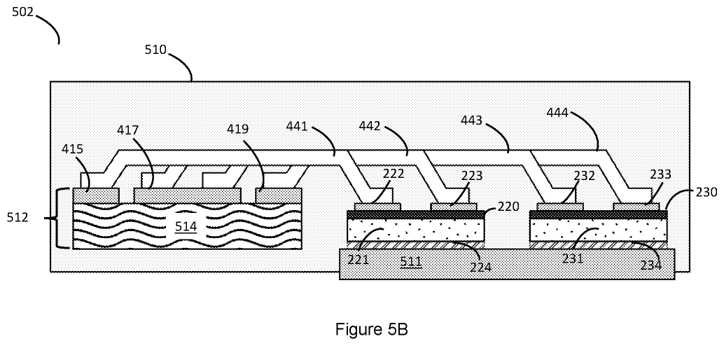

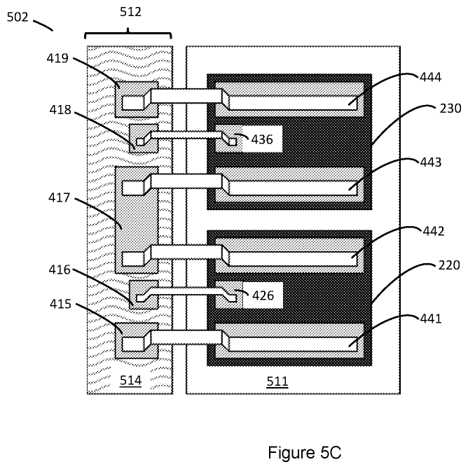

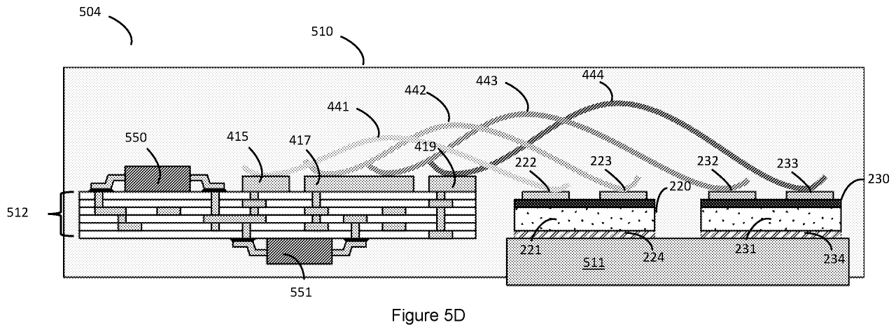

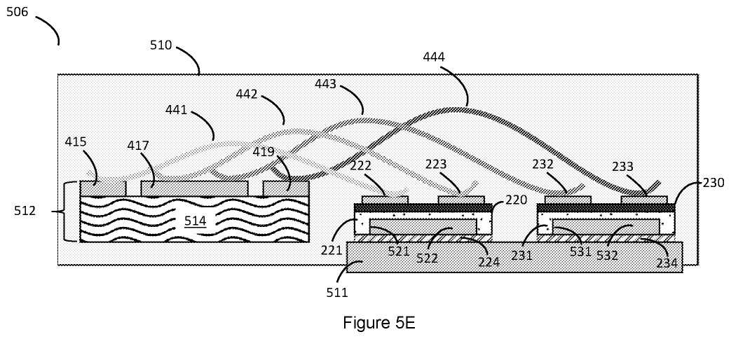

FIG. 5A is an illustrative cross-sectional side view of a module 500 for another implementation. Module 500 is similar to module 400 of FIG. 4B. Module 500 includes a package cover 510. The first device 220 and the second device 230 are directly mounted to the high thermally conductive structure package base 511. In contrast to module 400 of FIG. 4B, the PCB board 512 is physically separated from the structural package base 511 and an insulating molding compound 520 can be formed inside of module 500 and between the PCB board 512 and the package base 511. The physical separation and the molding compound 520 act to isolate the PCB from the package base. Isolating PCB board 512 from package base 511 can allow for more complex integration of additional electronic components described in more detail in the forthcoming figures.

FIG. 5B is an illustrative cross-sectional side view of another module 502. Here, connectors 441-444 are depicted as metal clips (e.g., Cu clips) as opposed to individual wire-bonds as in module 500 of FIG. 5A. Connectors 441-444 may also be wire-ribbons or other appropriate electrical connector. FIG. 5C is a plan view of module 502. As seen in FIG. 5C, each of the metal clips 441-444 connects the first device 220 and the second device 230, respectively, to the PCB 512. FIG. 5C also shows the first gate electrode 426 of the first device 220 connected to top metal layer 416 with a metal clip, and the second gate electrode 436 of the second device 230 connected to top metal layer 418 with a metal clip. As seen in the plan view of module 502 in FIG. 5C, the PCB 512 is located on a first side of the first and second devices 220 and 230. The second device 230 is located on a second side of the first device 220, where the second side of device 220 is adjacent to the first side of device 220.

FIG. 5D is an illustrative cross-sectional side view of an electronic module 504 that is similar to module 500 of FIG. 5A. However, module 504 includes a first electronic component 550 mounted to PCB 512. Electronic component 550 can be similar to electronic component 450 of FIG. 4C. Electronic component 550 is mounted on a first side of PCB 512 which can be the same side of the PCB where top metal layers 415-419 are formed. Module 504 can further include a second electronic component 551 similar to the first electronic component 550, however the second electronic component 551 is mounted on a second side of the PCB 512 opposite the first side. The PCB board 512 can be a multi-layer board, i.e., having more than one, or more than 2 metal layers of electrical routing, buried in the bulk of the board. These metal routing layers can be used to electrically connect electronic components 550 and 551 to the top metal layers 415-419.

FIG. 5E is an illustrative cross-sectional side view of an electronic module 506 that is similar to module 500 of FIG. 5A. However, module 506 has been modified to improve the thermal efficiency compared to module 500. As seen in FIG. 5E, a portion of the substrate 221 below the active III-N material structure of the first device 220 is removed. The removal of this portion of the substrate creates a recess in the bottom surface of the substrate 221, so that the substrate provides a “tub” 521. The tub 521 can subsequently be filled with a high thermal conductive material 522, such as a metal or epoxy, etc. Similarly, a portion of the substrate 231 below the active III-N material structure of the second device 230 is removed to create a recess in the bottom surface of the substrate 231, thus forming a tub 531. The tub 531 can subsequently be filled with a high thermal conductive material 532. The formation of the tubs and subsequently filling with a high thermal conductive material can increase the ability of the module 506 to remove heat from the active layers of the devices 220 and 230 out to a heatsink (not shown) that can be attached to the thermally conductive package base 511.

FIG. 6A is an illustrative cross-sectional side view and FIG. 6B is a plan view of a module 600 that is similar to the module 500 of FIG. 5A, except that module 600 includes an monolithically integrated first and second power device. As seen in FIG. 6A, the first device 220 and second device 230 are integrated on to a common insulating substrate 621 (e.g., sapphire substrate) to form an integrated device 620. The III-N HEMT structure of the first device 220 and the III-N HEMT structure of the second device 230 are electrically isolated from one another by isolation region 625. The isolation region 625 can be formed by either etching a trench through the entire III-N HEMT structure of integrated device 620 and partially (optionally) into the insulating substate 621 (between the drain electrode of device 220 and the source electrode of device 230) or by ion implantation to create the isolation region 625. The drain electrode of the first device 220 and the source electrode of the second device 230 can be connected together by an integrated metal layer 228 (or optionally electrically connected together with external circuitry).

Integrated device 620 is connected to the thermally conductive structural package base 511 with adhesion layer 624, which can be similar to adhesion layer 224 previously described in FIG. 2A. By forming integrated device 620 on a common insulating substrate 621, the first device 220 and the second device 230 can be integrated without negative performance affects, which would not be possible if devices 220 and 230 were formed on a conductive or semi-conductive substrate such as silicon or silicon carbide. In fact, when monolithically integrated on a conductive or semi-conductive substrate, devices can suffer from cross back-gating, a situation where devices are capacitively coupled with the conducting or semiconducting substrate and can therefore interfere with each-other, disrupting their functionality, performance and/or reliability. For example, when operating at high-voltage, a first device can raise the substrate potential to high-voltage. In turn, the substrate can act as a parasitic back-gate on a second device, applying undesired high-voltage to the active region of the second device, disrupting performance and reliability (for example, through worsened buffer charge-trapping, electric-field and leakage). In contrast, cross back-gating is not an issue on insulating substrates, e.g., a sapphire substrate, such as substrate 621, because capacitive coupling between the devices and the substrate 621 is negligible. Therefore the devices do not interfere with each other during operation, preserving functionality, performance and reliability. FIG. 6B is a plan view which depicts module 600 formed with metal clips.

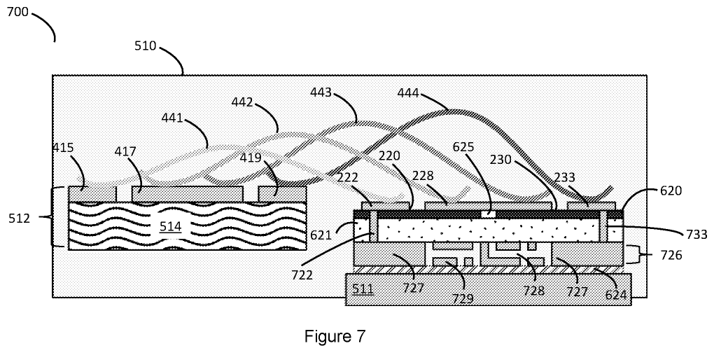

FIG. 7 is a side view of a module 700 which is similar to module 600 of FIG. 6A, except that module 700 includes integrated electronic components and circuitry formed on a reverse side of the insulating substate 621, opposite the source and drain electrodes of integrated device 620. The reverse side circuitry depicted in region 726 can included reverse side power and/or thermal lines 727, integrated components 728 (e.g., capacitors, resistors, diodes, inductors, ICs, etc.), and signal lines 729 (e.g., made of high conductivity material, metal). The reverse side power lines 727 can be connected to the source electrode 222 of the first power device 220 with a via 722 and to the drain electrode 233 of the second power device 230 with another via 733. Vias 722 and 733 are formed through the insulating substrate 621 and a metal layer of the via connects the source and drain electrodes of integrated device 620 to the reverse side circuitry 726.

A first advantage of reverse-side circuitry is reduced parasitic inductances. In fact, the connection of the top-side device 620 with the back-side components 726 can have much smaller stray inductance than the connection between the power device and components placed on the board through wire-bonds and/or clips and/or ribbon bonds and/or board traces. Therefore, back-side circuitry can help reduce power losses and EMI due to stray inductances, and can enable higher operating frequencies. A second advantage of reverse-side circuitry is a more compact design with less usage of area on the board, therefore leading to system miniaturization, desired in applications with stringent requirements on size, for example integrated motor drives, and miniaturized, distributed Internet-of-Things devices and systems.

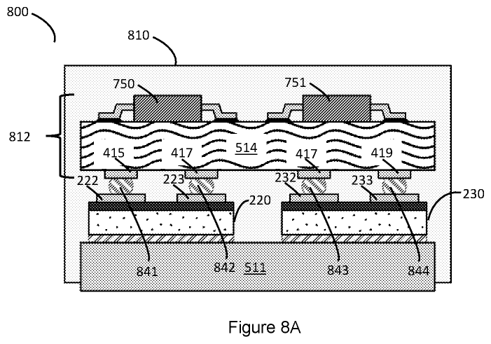

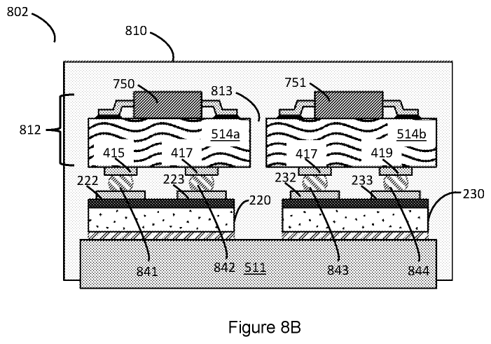

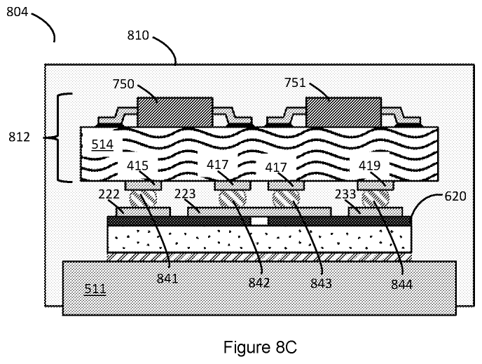

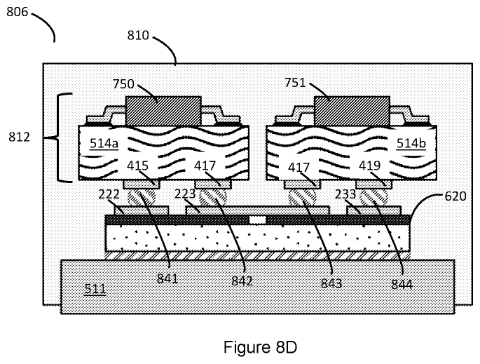

FIG. 8A is a side view of a module 800 which is similar to the module 504 of FIG. 5D. However, module 800 is assembled using a flip-chip technique to reduce the overall module size and cost, as well as improve performance module performance by reducing circuit inductances. The module 800 includes a package 810. Package 810 includes a PCB 812 which can be similar to PCB 512 except that PCB 812 is inverted (or flipped) compared to PCB 512 and the PCB 812 is electrically connected to the first device 220 and the second device 230 using solder balls instead of wire-bonds or metal clips. PCB 812 includes an insulating layer 514 and top metal layers (415/417/419). The first top metal layer 415 is electrically connected to the source pad 222 of the first device 220 with solder ball 841. The second top metal layer 417 is electrically connected to the drain pad 223 of the first device 220 and the source pad 232 of the second device 230 with solder balls 842 and 843, respectively. Third top metal layer 419 is electrically connected to the drain pad 233 of the second device 230 with solder 844. PCB 812 may optionally include additional electronic components such as component 750 and/or 751 which can be similar to the electronic components 550/551 described in FIG. 5D. Components 750 and 751 can be formed on a side of the insulating layer 514 opposite the top metal layers 415/417/419 in order to reduce the overall footprint of module 800.

Furthermore, it may be desirable to have separate independent insulating PCB layers configured to the first and second power devices. As shown in module 802 of FIG. 8B, PCB layer 812 has been configured into two electrically and physically isolated pieces by forming an insulating layer with a first portion 514a and a second portion 514b. The first portion 514a and the second portion 514b are separated by isolation region 813, which can either be a trench etch through the insulating layer 514 or an air gap between two independent insulating layers. For example, the air gap can be provided by two separate PCBs. The advantage of separating the PCB boards can be to improve robustness and reliability during thermal and power cycling. In fact, different thermal expansion coefficients between the different materials forming the semiconductor power device and the boards can lead to undesired mechanical stress during thermal cycling, possibly resulting in lower reliability. By separating the boards, the mechanical stress can be partially or fully relaxed.

A module 804 shown in FIG. 8C is similar to the module 800 of FIG. 8A, but the module 804 in FIG. 8C is formed using an monolithically integrated power device 620 similar to the integrated power device 620 described in FIG. 6A, instead of using two discrete devices, like the first device 220 and second device 230 shown in FIG. 8A. Using an integrated power device 620 in the module 804 can further reduce complexity and shrink the overall size of the module compared to module 800. This can realize improved device performance and reduced system cost.

Furthermore, it may be desirable to have separate independent insulating PCB layers configured to the first and second power devices. As shown in module 806 of FIG. 8D, PCB layer 812 has been configured into two electrically and physically isolated pieces by forming insulating layer in a first portion 514a and a second portion 514b. The first portion 514a and the second portion 514b are separated by isolation region 813, which can either be a trench etch through the insulating layer 514 or PCB 812 can be formed of two independent insulating layers.

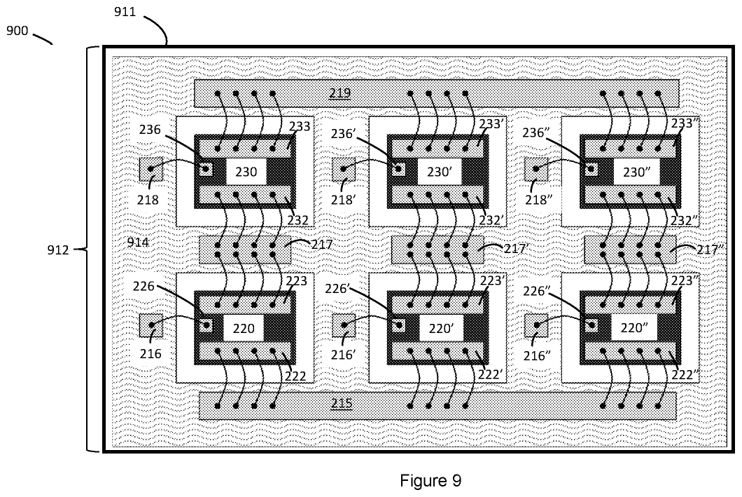

FIG. 9 is a plan view of an electronic module 900. Module 900 is similar to the half-bridge circuit used in module 200 of FIG. 2B, however, module 900 is configured as a 3-phase full bridge circuit. Module 900 includes a package base 911 and a PCB layer 912. PCB 912 includes an insulating 914. PCB 912 further includes top metal layer 219 which is connected to a high-voltage terminal of module 900. The high-voltage terminal is configured to be connected to a circuit high-voltage power supply. PCB 912 further includes top metal layers (218/218′/218″) which are connected respectfully, to the first-phase, second-phase, third-phase gate input terminals of module 900. PCB 912 further includes top metal layer 215 which is connected to a ground terminal of module 900. The ground terminal of module 900 is configured to be connected to a circuit ground.

Module 900 includes a first high-side switch 230, and second high-side switch 230′, and a third high-side switch 230″. Module 900 further includes a first low-side switch 220, a second low-side switch 220′, and a third low-side switch 220″. The drain electrodes (233/233′/233″) of the high-side switches (230/230′/230″) are each connected to the top metal layer 219. The source electrode 232 of the first high-side switch 230 and drain electrode 223 of first low-side switch 220 are each connected to the top metal layer 217. The source electrode 232′ of the second high-side switch 230′ and drain electrode 223′ of second low-side switch 220′ are each connected to the top metal layer 217′. The source electrode 232″ of the third high-side switch 230″ and drain electrode 223″ of third low-side switch 220″ are each connected to the top metal layer 217″. The source electrodes (222/222′/222″) of the low-side switches (220/220′/220″) are each connected to the top metal layer 215. The input gates electrodes of the high-side switches (230/230′/230″) are respectfully connected to the top metal layers (218/218′/218″). The input gates electrodes of the low-side switches (220/220′/220″) are respectfully connected to the top metal layers (216/216′/216″). Each of the insulating substrates of the high-side switches and low-side switches of module 900 are physically mounted to the package base of 911 of module 900 through a via portion of PCB 912 where the insulating layer 914 has been removed or is otherwise not present.

Although not shown for simplicity. Any of the modules 400, 402, 404, 500, 502, 504, 600, 700, 800, 802, 804, 806, or 900 can included a low-voltage enhancement mode device configured similar to device 320 shown in FIG. 3 to either and/or both the source pad 222 of the first device 220 or the source pad 232 of the second device 230.

Although not shown for simplicity, all the modules described herein contain module leads which extend outside of the package case and are configured to be connected to external circuitry. These module leads can be power terminals, gate drive terminals, ground terminals, or any other package lead required for proper operation. In addition, all the modules described herein can be connected to a heat sink. The heat sinks can be externally connected. Depending on the heat sink configuration, the modules described herein can be either top-side cooled, or bottom-side cooled.

A number of implementations have been described. Nevertheless, it will be understood that various modifications may be made without departing from the spirit and scope of the techniques and devices described herein. Accordingly, other implementations are within the scope of the following claims.

What is claimed is:

1. An electronic component, comprising:
an electronic component package comprising a high thermally conductive package base;
a first lateral III-N device comprising a first insulating substrate, the first lateral III-N device comprising a first side and a second side, wherein a first III-N material structure is on the first side of the first lateral III-N device; and
a second lateral III-N device comprising a second insulating substrate, the second lateral III-N device comprising a first side and a second side, wherein a second III-N material structure is on a first side of the second lateral III-N device;
wherein the second side of the first lateral III-N device is directly mounted and physically attached to the package base, and the second side of the second lateral III-N device is directly mounted and physically attached to the thermally conductive package base.

2. The component of claim 1, wherein a backmetal layer is disposed on the second side of the first and second lateral III-N devices, and the backmetal layer is attached to the thermally conductive package base using a thermally conductive solder, a thermally conductive epoxy, or a thermally conductive solder paste.

3. The component of claim 1, wherein the first and the second insulating substrates are sapphire substrates with a thickness greater than 50 μm and a breakdown voltage greater than 1200V.

4. The component of claim 1, further comprising a printed circuit board (PCB) within the electronic component package, the PCB comprising an insulating layer, a first side, and a second side opposite the first side, wherein the first side of the PCB includes a first metal layer physically attached to the package base.

5. The component of claim 4, wherein the second side of the PCB includes a second metal layer; and
the second metal layer includes at least a first portion, a second portion, and a third portion, wherein the first portion, the second portion, and the third portion are each electrically isolated from the other portions; and
a drain electrode of the first lateral III-N device is electrically connected to the first portion, a source electrode of the first lateral III-N device is electrically connected to the second portion, a drain electrode of the second lateral III-N device is electrically connected to the second portion, and a source electrode of the second lateral III-N device is electrically connected to the third portion.

6. The component of claim 4, further comprising a first vertical MOSFET device, wherein a drain electrode of the first vertical MOSFET device is electrically connected and physically attached to a source electrode of the first lateral III-N device.

7. The component of claim 6, further comprising a second vertical MOSFET device, wherein a drain electrode of the second vertical MOSFET device is electrically connected and physically attached to a source electrode of the second lateral III-N device.

8. The component of claim 7, wherein the second side of the PCB includes a second metal layer; and
the second metal layer includes at least a first portion, a second portion, and a third portion, wherein the first portion, the second portion, and the third portion are each electrically isolated from the other portions; and
a drain electrode of the first lateral III-N device is electrically connected to the first portion, a source electrode of the first vertical MOSFET device is electrically connected to the second portion, a drain electrode of the second lateral III-N device is electrically connected to the second portion, and a source electrode of the second vertical MOSFET device is electrically connected to the third portion.

9. The component of claim 5, further comprising a resistor, capacitor, or integrated circuit mounted to the second side of the PCB.

10. The component of claim 1, further comprising a printed circuit board (PCB) within the electronic component package, the PCB comprising an insulating layer, a first side, and a second side opposite the first side, wherein the PCB is physically isolated from the package base.

11. The component of claim 10, further comprising a resistor, capacitor, or integrated circuit mounted to the second side of the PCB and a resistor, capacitor, or integrated circuit mounted to the first side of the PCB.

12. An electronic module, comprising:
a high thermally conductive package base;
a substrate mounted to the thermally conductive package base, the substrate including comprising a first metal layer on an insulating layer, the first metal layer including a first portion, a second portion, and a third portion, the substrate further comprising a first opening and a second opening with the first metal layer and the insulating layer removed in the first opening and the second opening to expose a top surface of the package base;
a first semiconductor device mounted to the thermally conductive package base in the first opening; and
a second semiconductor device mounted to the thermally conductive package base in the second opening;
a package cover attached to the package base to enclose the substrate, the first semiconductor device and the second semiconductor device.

13. The electronic module of claim 12, wherein a drain electrode of the first semiconductor device is electrically connected to the first portion of the first metal layer, a source electrode of the first semiconductor device is electrically connected to the second portion of the first metal layer, a drain electrode of the second semiconductor device is electrically connected to the second portion of the first metal layer, and a source electrode of the second semiconductor device is electrically connected to the third portion of the first metal layer.

14. The electronic module of claim 13, wherein the first portion of the first metal layer is connected to a high-voltage terminal, the second portion of the first metal layer is connected to an output terminal, and the third portion of the first metal layer is connected to a ground terminal.

15. The electronic module of claim 14, wherein the first semiconductor device and the second semiconductor device form a half-bridge circuit.

16. The electronic module of claim 13, wherein the first semiconductor device and the second semiconductor device is a lateral III-N transistor, and a III-N material structure of the transistors are formed over sapphire substrates.

17. The electronic module of claim 12, further comprising a third semiconductor device and a fourth semiconductor device, wherein a drain electrode of the third semiconductor device is mounted to a source electrode of the first semiconductor device and a drain electrode of the fourth semiconductor device is mounted to a source electrode of the second semiconductor device; and
a drain electrode of the first semiconductor device is electrically connected to the first portion of the first metal layer, a source electrode of the third semiconductor device is electrically connected to the second portion of the first metal layer, a drain electrode of the second semiconductor device is electrically connected to the second portion of the first metal layer, and a source electrode of the fourth semiconductor device is electrically connected to the third portion of the first metal layer.

18. The electronic module of claim 17, wherein the first portion of the first metal layer is connected to a high-voltage terminal, the second portion of the first metal layer is connected to an output terminal, and the third portion of the first metal layer is connected to a ground terminal.

19. The electronic module of claim 18, wherein the first semiconductor device and the second semiconductor device form a half-bridge circuit.

20. The electronic module of claim 17, wherein the first semiconductor device and the second semiconductor device is a lateral III-N transistor, a III-N material structure of the transistors are formed over sapphire substrates, and the third semiconductor device and the fourth semiconductor device are vertical silicon MOSFET transistors.

21. An electronic module, comprising:
a high thermally conductive package base, a high-voltage terminal, an output terminal, a ground terminal;
a high-side switch comprising a first III-N depletion-mode transistor and a first enhancement-mode transistor;
a low-side switch comprising a second III-N depletion-mode transistor and a second enhancement-mode transistor; and
a package cover attached to the package base to enclose the substrate, high-side switch and low-side switch,
wherein a drain electrode of the first III-N depletion-mode transistor is electrically connected to the high-voltage terminal, a source electrode of the first enhancement-mode transistor is electrically connected to the output terminal, a drain electrode of the second III-N depletion-mode transistor is electrically connected to the output terminal, a source electrode of the second enhancement-mode terminal is electrically connected to the ground terminal;
and wherein a substrate of the first and second III-N depletion-mode transistors are directly mounted and physically attached to the high thermally conductive package base.

22. The electronic module of claim 21, wherein the substrates of the first and second III-N depletion-mode transistors are sapphire substrates.

23. The electronic module of claim 22, wherein the high-side switch and the low-side switch form a half-bridge circuit.

24. The electronic module of claim 23, wherein the first and second III-N depletion-mode transistors are lateral GaN HEMT transistors.

25. The electronic module of claim 24, wherein the first and second enhancement-mode transistors are vertical silicon MOSFET transistors.

26. The electronic module of claim 25, wherein a drain of the first enhancement-mode transistor is directly physically attached to a source of the first III-N depletion-mode transistor, and a drain of the second enhancement-mode transistor is directly physically attached to a source of the second III-N depletion-mode transistor.
